(19) United States
(12) Patent Application Publication
(10) Pub. No.: US 2021/0321528 A1
(43) Pub. Date: Oct. 14, 2021

(54) SYSTEM AND METHOD FOR SYSTEM LEVEL COOLING OF AN ARRAY OF MEMORY MODULES

(71) Applicant: Dell Products L.P., Round Rock, TX (US)

(72) Inventors: Robert Boyd Curtis, Georgetown, TX (US); Kevin Warren Mundt, Austin, TX (US)

(21) Appl. No.: 16/846,026

(22) Filed: Apr. 10, 2020

(51) Int. Cl. H05K 7/20; G06F 1/20; H05K 5/00

(52) U.S. Cl. CPC H05K 7/2039; G06F 1/20; F28F 2215/12; H05K 5/0021; G06F 2200/201; H05K 7/20272

(57) ABSTRACT

A cooling system interface for system cooling of a plurality of memory modules comprises a plurality of thermal interface material (TIM) blankets and a heatsink comprising a plurality of conductive fins. A TIM blanket may be positioned on each memory module and the heatsink may be positioned relative to the array of memory modules such that a conductive fin is positioned between two adjacent memory modules and a conduction fin is positioned relative to the memory modules on each end of the array. Each TIM blanket comprises a thickness based on components on the memory module and each conduction fin has a rigidity and thickness to ensure conformal contact between the TIM blanket and a conduction fin. Slidable contact between the conduction fins and TIM blankets allows the cooling system interface to be removed for servicing the memory module.

### BACKGROUND

### Field of the Disclosure

This disclosure relates generally to information handling systems and, more particularly, to cooling systems and cooling system interfaces for system level cooling of an array of memory modules.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Embodiments disclosed herein may be generally directed to cooling systems and cooling system interfaces for system level cooling of an array of memory modules. A thermal interface material (TIM) blanket is positioned over each memory module. A heatsink with a plurality of conduction fins is positioned on the array of memory modules such that each conduction fin is in contact with at least one TIM blanket and applies pressure to the TIM blanket to cause conformal contact between the TIM blanket and all components on a corresponding memory module. The heatsink comprises a top surface for interfacing with elements of a cooling system, including one or more of a plurality of convection fins for positioning in an airflow and a conduit for liquid cooling the array of memory modules.

### BRIEF DESCRIPTION OF THE DRAWINGS

For a more complete understanding of the invention and its features and advantages, reference is now made to the following description, taken in conjunction with the accompanying drawings, in which:

FIG. 1 is a block diagram of selected elements of an embodiment of an information handling system;

FIG. 2 is an exploded perspective view of an exemplary array of memory modules and a cooling system interface for system level cooling of the array of memory modules;

FIGS. 3A and 3B depict an exploded perspective view and an end view, respectively, of the array of memory modules and the cooling system interface depicted in FIG. 2 with one embodiment of a cooling system for system level cooling of the array of memory modules;

FIG. 4 depicts a simulated image of a heat distribution profile of a memory module in an airflow, illustrating the effects of convective heat transfer on a memory module in the array of memory modules; and

FIG. 5 depicts a simulated image of a heat distribution profile of a memory module in the array of memory modules as depicted in FIG. 3B, illustrating the effects of system level cooling on the memory module.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

As used herein, a hyphenated form of a reference numeral refers to a specific instance of an element and the un-hyphenated form of the reference numeral refers to the collective or generic element. Thus, for example, memory module “134-1” refers to an instance of a memory module class, which may be referred to collectively as memory modules “134” and any one of which may be referred to generically as a memory module “134.”

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and one or more video displays. The information handling system may also include one or more buses operable to transmit communication between the various hardware components.

Information handling systems may use memory modules such as Dual In-Line Memory Modules (DIMMs) that contain components including one or more controllers and many random access memory (RAM) chips connected by pins to a motherboard in a chassis. Each RAM chip and controller uses power, and power usage by memory modules, particularly DIMMs, is increasing as DIMM capacities are expanding beyond 64 GB load reduction DIMMs (LRDIMMs). For example, power usage by LRDIMMs at 128 GB are reaching approximately 12 W in some platforms and power usage by 256 GB LRDIMMs are expected to reach even higher power usage levels, resulting in higher heat production. Furthermore, Double Data Rate 5 (DDR5) is a type of Synchronous Dynamic Random Access Memory (SDRAM) in which power usage is targeted at 15-18 W.

At these power levels, it is difficult to provide sufficient cooling to the memory modules. One approach involves increasing airflow past the memory module. However, increasing airflow requires increasing fan speeds which requires more fan power and produces more acoustic noise. One option to airflow cooling is liquid cooling. However, implementation of liquid cooling for a memory module is more expensive and difficult to implement. In the next generation of DIMMs, the number of components on a memory module is expected to increase and the spacing between components is expected to decrease, making it more difficult to implement the above-mentioned cooling systems.

Embodiments disclosed herein include a system level cooling system and a cooling system interface configured to facilitate system level cooling of an array of memory modules. A thermal interface material (TIM) blanket may be positioned on each memory module such that the TIM blanket can contact all components on at least one side of the memory module. The TIM blanket has a thickness and pliability to allow conformal contact with each component on at least one side of the memory module. The cooling system interface further comprises a plurality of conduction fins. Each conduction fin has a thickness and rigidity configured to apply a pressure to the TIM blanket. The pressure applied to the TIM blanket causes conformal contact between the TIM blanket and each component on at least one side of the memory module. The conduction fins are positioned relative to the array of memory modules such that each memory module is between two conduction fins.

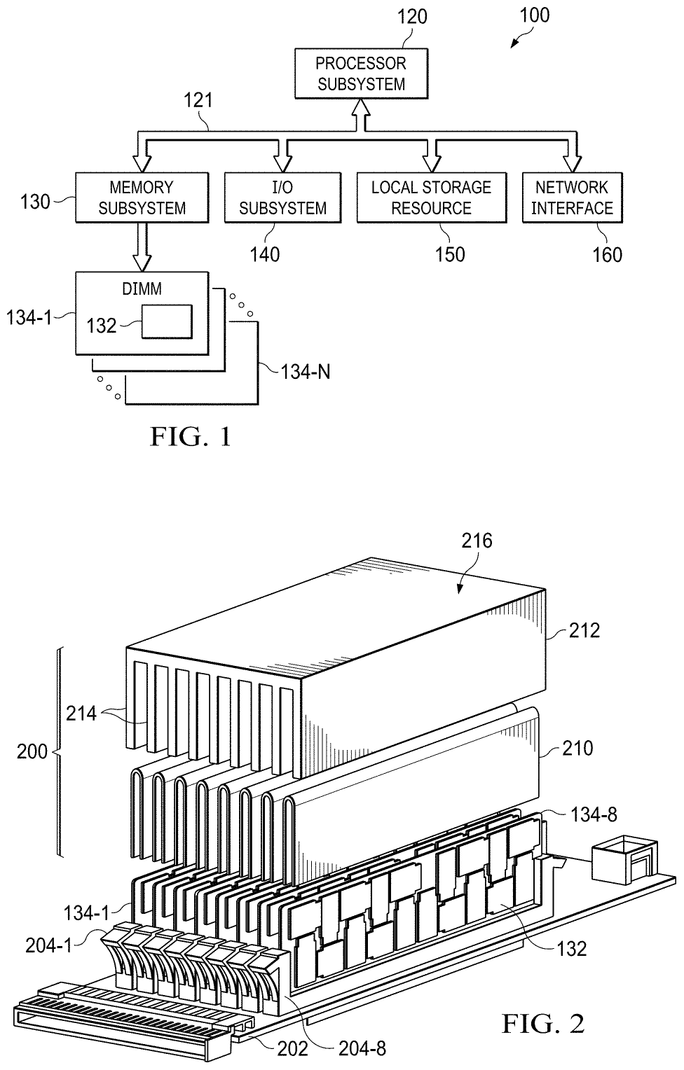

Embodiments disclosed herein are described with respect to arrays of memory modules but may also be practiced with other arrays of circuit boards with heat generating components. Particular embodiments are best understood by reference to FIGS. 1-2, 3A-3B and 4-5 wherein like numbers are used to indicate like and corresponding parts.

Turning to the drawings, FIG. 1 illustrates a block diagram depicting selected elements of an embodiment of information handling system 100. It is noted that FIG. 1 is not drawn to scale but is a schematic illustration.

As shown in FIG. 1, components of information handling system 100 may include, but are not limited to, a processor subsystem 120, which may comprise one or more processors, and a system bus 121 that communicatively couples various system components to processor subsystem 120 including, for example, a memory subsystem 130, an I/O subsystem 140, local storage resource 150, and a network interface 160. Memory 130 may include an array of memory modules 134 installed on a motherboard, wherein each memory module 134 comprises a plurality of components 132 such as memory chips.

Processor subsystem 120 may comprise a system, device, or apparatus operable to interpret and execute program instructions and process data, and may include a microprocessor, microcontroller, digital signal processor (DSP), application specific integrated circuit (ASIC), or another digital or analog circuitry configured to interpret and execute program instructions and process data. In some embodiments, processor subsystem 120 may interpret and execute program instructions and process data stored locally (e.g., in memory subsystem 130). In the same or alternative embodiments, processor subsystem 120 may interpret and execute program instructions and process data stored remotely (e.g., in a network storage resource).

System bus 121 may refer to a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

Memory subsystem 130 may comprise a system, device, or apparatus operable to retain and retrieve program instructions and data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down. Memory subsystem 130 may comprise an array of memory modules 134 with at least one side of each memory module 134 comprising a plurality of components 132 such as memory chips storing random access memory (RAM) and controllers for facilitating the storage and retrieval of information to and from memory chips.

In information handling system 100, I/O subsystem 140 may comprise a system, device, or apparatus generally operable to receive and transmit data to or from or within information handling system 100. I/O subsystem 140 may represent, for example, a variety of communication interfaces, graphics interfaces, video interfaces, user input interfaces, and peripheral interfaces. In various embodiments, I/O subsystem 140 may be used to support various peripheral devices, such as a touch panel, a display adapter, a keyboard, an accelerometer, a touch pad, a gyroscope, or a camera, among other examples. In some implementations, I/O subsystem 140 may support so-called ‘plug and play’ connectivity to external devices, in which the external devices may be added or removed while information handling system 100 is operating.

Local storage resource 150 may comprise computer-readable media (e.g., hard disk drive, floppy disk drive, CD-ROM, and other type of rotating storage media, flash memory, EEPROM, or another type of solid-state storage media) and may be generally operable to store instructions and data.

Network interface 160 may be a suitable system, apparatus, or device operable to serve as an interface between information handling system 100 and a network (not shown). Network interface 160 may enable information handling system 100 to communicate over a network using a suitable transmission protocol or standard. In some embodiments, network interface 160 may be communicatively coupled via a network to a network storage resource (not shown). A network coupled to network interface 160 may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, the Internet or another appropriate architecture or system that facilitates the communication of signals, data and messages (generally referred to as data). A network coupled to network interface 160 may transmit data using a desired storage or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), or any combination thereof. A network coupled to network interface 160 or various components associated therewith may be implemented using hardware, software, or any combination thereof.

During operation of information handling system 100, processor subsystem 120 may communicate with memory subsystem 130 to store and retrieve information. Memory subsystem 130 may store and retrieve information in components 132 on memory modules 134. As information is stored or retrieved from memory subsystem 130, components 132 generate heat. The amount of heat generated by components 132 may vary and the amount of heat generated by memory modules 134 may also vary.

FIG. 2 depicts an exploded perspective view of an exemplary motherboard 202 with an array of memory modules 134 (memory modules 134-1 to 134-8 as shown) installed in sockets 204 (sockets 204-1 to 204-8 as shown) thereon. Each side of memory modules 134 may have a plurality of components 132 such as memory chips for storing information in random access memory (RAM) and controllers or processors for managing the storage and retrieval of information to/from memory chips. The size, position and orientation of each component 132 and the spacing or separation between components 132 may vary.

FIG. 2 further depicts an embodiment of a cooling system interface to facilitate system level cooling of an array of memory modules 134. Embodiments of cooling system interface 200 may comprise a plurality of thermal interface material (TIM) blankets 210 and heatsink 212. When cooling system interface 200 is positioned on the array of memory modules 134, heat generated by components 132 is transferred through TIM blankets 210 to conduction fins 214 for distribution along conduction fins 214 and for transferring to top surface 216.

Still referring to FIG. 2, TIM blankets 210 may be formed with a length and a width for positioning relative to memory modules 134. In some embodiments, each TIM blanket 210 may be positioned with a first edge on a first side of a memory module 134 (e.g., memory module 134-1) and TIM blanket 210 may be folded, bent or curved such that a second edge of TIM blanket 210 is positioned on an opposite side of the same memory module 134 (e.g., memory module 134-1). Each TIM blanket 210 may be formed from a thermal interface material having a thickness and pliability for conformal contact with each component 132 on memory module 134, discussed below in more detail.

Heatsink 212 may be formed with a plurality of conduction fins 214 for contact with a plurality of TIM blankets 210, wherein each conduction fin 214 has a length, width, thickness and pliability to ensure TIM blankets 210 maintain conformal contact with all components 132 on a memory module 134. Conduction fins 214 are formed from a material with a thermal conductivity to facilitate heat transfer from TIM blankets 210 to top surface 216 and allow heat distribution along conduction fins 214. The number of conduction fins 214 may be based on the number of memory modules 134 to ensure all components 132 on each memory module 134 are in conformal contact with a TIM blanket 210. As depicted in FIG. 2, for an array of eight memory modules 134 (e.g., memory modules 134-1 to 134-8) with components 132 on both sides of each memory module 134, heatsink 212 may have nine conduction fins 214 (e.g., conduction fins 214-1 to 214-9).

Top surface 216 may be configured for receiving heat energy from the plurality of conduction fins 214, for distributing heat along the length of each conduction fin 214 and across conduction fins 214 for interfacing with elements of a cooling system. As depicted in FIG. 2, top surface 216 may be formed as a smooth, continuous surface.

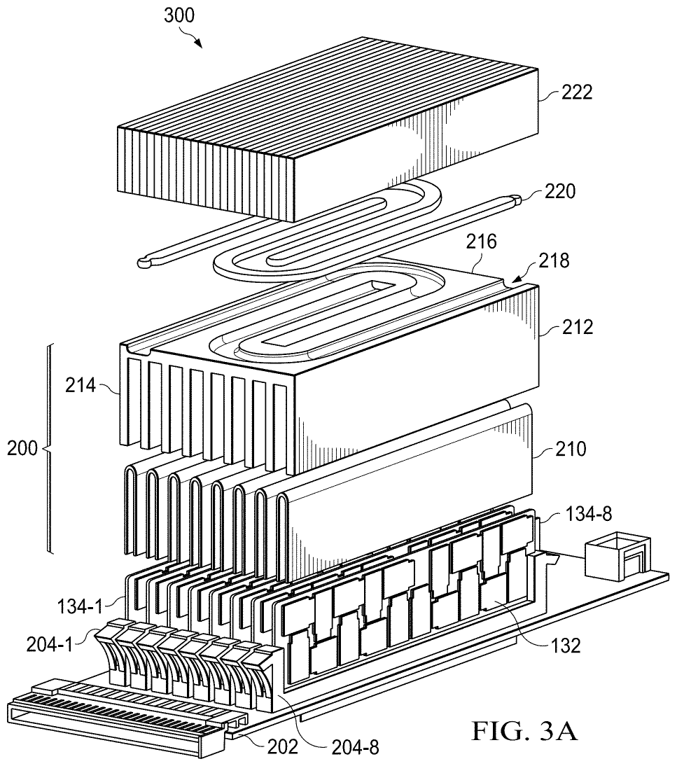

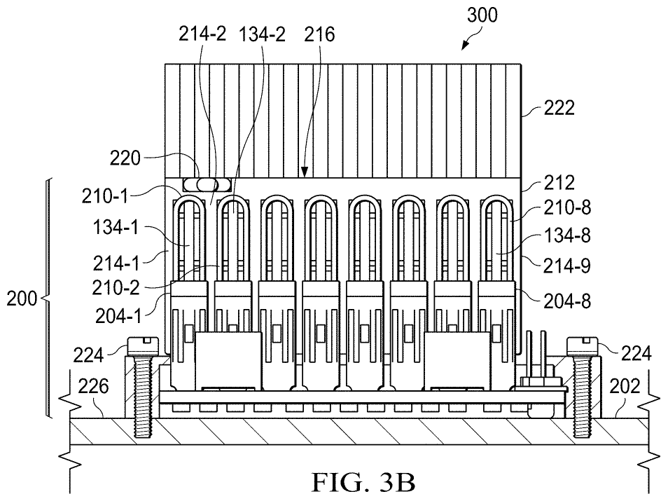

As the number of components 132 on memory modules 134 increases and the spacing between components 132 decreases, implementation of effective cooling systems will be more difficult. Referring to FIGS. 3A and 3B, embodiments of a cooling system for system level cooling of an array of memory modules 134 may include embodiments of cooling system interface 200 and may further include one or more of liquid cooling conduits 220 and convection fins 222 in contact with cooling system interface 200.

As shown in FIG. 3A, embodiments of cooling system interface 200 may comprise heatsink 212 with top surface 216 formed with groove 218 for receiving one or more conduits 220 of a fluid-cooling type heat transfer system 300.

Conduits 220 may comprise heat pipes or other mechanisms that allow phase changing between liquids and gases or vapors. As shown in FIG. 3A, cooling system 300 may include two conduits 220. Each conduit 220 may be configured with a first end for positioning near a midline of the array of memory modules 134 such that a first length is near the center of the array, extends to a first end of the array and bends such that a second length is near a side of the array. Other configurations of conduits 220 are possible.

Also depicted in FIGS. 3A and 3B, embodiments of cooling system 300 may comprise a plurality of convection fins 222 for contact with top surface 216 and conduits 220. Convection fins 222 may be formed from a material and configured with a number of fins, thickness and height for receiving heat from heatsink 212. Convection fins 222 may be independent of the number of conduction fins 214 or memory modules 134 and convection fins 222 may be shorter, thinner and/or less rigid than conduction fins 214. Convection fins 222 may be soldered or otherwise coupled to top surface 216 of heatsink 212 depicted in FIG. 2 or coupled to top surface 216 including conduits 220 as depicted in FIG. 3A. Convection fins 222 may be aligned with memory modules 134 (as shown in FIGS. 3A and 3B) or oriented transverse or at some other angle (not shown) relative to memory modules 134.

As described above, embodiments of cooling system interface 200 may efficiently transfer heat away from memory modules 134 to top surface 216 for interfacing with embodiments of a system level cooling system.

Referring to FIG. 3B, embodiments of cooling system 300, including cooling system interface 200 are configured for system level removal of heat from memory modules 134 of an array of memory modules 134.

As used herein, conformal contact may refer to contact between the plurality of TIM blankets 210 and the array of memory modules 134 such that heat generated by components 132 (not visible in FIG. 3B) may be transferred away from components 132 using conductive heat transfer. Conformal contact may refer to contact between thermal interface material and a surface of the component 132 and may also include contact caused by the thermal interface material filling in spaces between components 132 and/or contact between the thermal interface material and a circuit board to which components 132 are mounted. In some embodiments, conformal contact between TIM blankets 210 and memory modules 134 comprises contact between thermal interface material and each component 132. In some embodiments, conformal contact between TIM blankets 210 and memory modules 134 comprises contact between the thermal interface material and each component 132 such that the thermal interface material conforms to the shape of each component 132. In some embodiments, conformal contact between TIM blankets 210 and memory modules 134 comprises contact between the thermal interface material and each component 132 and the thermal interface material is present between adjacent components 132. In some embodiments, conformal contact between TIM blankets 210 and memory modules 134 comprises contact with each component 132 and contact between the thermal interface material and at least a portion of a circuit board on which components 132 are mounted.

To ensure conformal contact with all components 132 on a side of a memory module 134, each TIM blanket 210 may be formed from a thermal interface material having a thickness and pliability selected to ensure contact with each component 132 on the memory module 134. In contrast, if TIM blankets 210 are too thin or not pliable, a TIM blanket 210 may contact most—but not all—components 132 on a memory module 134. If an air gap is present, a lack of airflow past components 132 will result in higher temperatures of those components 132. Alternatively, a TIM blanket 210 that is too thick may interfere with the ability to position conduction fins 214 between memory modules 134 without damaging components 132, memory modules 134, TIM blankets 210 and/or conduction fins 214.

Each conduction fin 214 may have a thickness or rigidity for applying pressure to the thermal interface material to cause conformal contact between a TIM blanket 210 and all components 132 on at least one side of a memory module 134. The thickness and rigidity of each conduction fin 214 may depend on a separation distance between two adjacent memory modules 134, a thickness and pliability of the thermal interface material forming each TIM blanket 210 and a thickness of components 132 on each memory module 134. For example, as depicted in FIG. 3B, conduction fin 214-2 may be positioned between adjacent memory modules 134-1 and 134-2 and have sufficient thickness to apply pressure to TIM blankets 210-1 and 210-2 to cause conformal contact with components 132 on each memory module 134-1 and 134-2. Furthermore, as depicted in FIG. 3B, conduction fin 214-1 positioned by only memory module 134-1 may have sufficient rigidity to apply pressure to the thermal interface material to cause conformal contact between TIM blanket 210-1 and each component 132 on one side of memory module 134-1.

Referring to FIGS. 2, 3A and 3B, cooling system interface 200 and cooling system 300 may be installed on an array of memory modules 134 installed in a plurality of sockets 204 on a motherboard 202.

During installation, a plurality of TIM blankets 210 may be positioned relative to an array of memory modules 134. FIGS. 2, 3A and 3B depict all TIM blankets 210 positioned relative to memory modules 134.

A plurality of TIM blankets 210 may be positioned on an array of memory modules 134 to ensure each TIM blanket 210 of a plurality of TIM blankets 210 contact all components 132 on at least one side of a memory module 134. In some embodiments, each TIM blanket 210 may be positioned with a first edge on a first side of a memory module 134 and the TIM blanket 210 may be folded, bent or curved such that a second edge of the TIM blanket 210 is positioned on an opposite side of the same memory module 134.

Heatsink 212 may be positioned with a plurality of conduction fins 214 positioned relative to spaces between memory modules 134.

Heatsink 212 may be advanced to position each conduction fin 214 proximate to a memory module 134 or between adjacent memory modules 134 to cause conformal contact between the TIM blanket 210 and components 132 on at least one side of a memory module 134. To facilitate advancement of conduction fins 214 and withdrawing conduction fins 214 relative to adjacent TIM blankets 210, one or more of TIM blankets 210 and conduction fins 214 may have a surface texture for slidable contact.

As conduction fins 214 are advanced between memory modules 134, a width of each conduction fin 214 applies a pressure to a corresponding TIM blanket 210 to cause conformal contact between the thermal interface material and components 132 on a corresponding memory module 134.

Heatsink 212 may be coupled to a chassis 226 using hardware 224, which may ensure conduction fins 214 are advanced completely and positioned relative to TIM blankets 210.

With system level cooling system interface 200 installed, heat generated by components 132 on memory modules 134 may be transferred by TIM blankets 210 to conduction fins 214. Conduction fins 214 allow heat distribution from areas on conduction fins 214 associated with hotter components 132 to areas on conduction fins 214 associated with cooler components 132 and facilitate heat transmission out of the array of memory modules 134 to top surface 216.

Installation of cooling system 300 may include the preceding steps and may also include installation of embodiments of conduits 220 or convection fins 222. For example, one or more conduits 220 may be positioned in one or more grooves 218 in top surface 216 for a liquid-cooling type system level cooling system and convection fins 222 may be coupled to top surface 216.

With system level cooling system 300 installed, heat generated by components 132 on memory modules 134 may be transferred by TIM blankets 210 to conduction fins 214. Conduction fins 214 allow heat distribution from areas on conduction fins 214 associated with hotter components 132 to areas on conduction fins 214 associated with cooler components 132 and facilitate heat transmission out of the array of memory modules 134 to top surface 216. Top surface 216 transfers heat to elements of cooling system 300, which may include conduits 220 in grooves 218 and convection fins 222.

In some situations, a memory module 134 may need to be replaced or otherwise removed from an array in information handling system 100. Embodiments of system level cooling system interface 200 and system level cooling system 300 facilitate individual replacement of memory modules 134.

Removal of a single memory module 134 from information handling system 100 may include removing hardware 224 coupling heatsink 212 to chassis 226, removing heatsink 212, identifying which memory module 134 to remove, removing TIM blanket 210 from the identified memory module 134, opening socket 204 corresponding to the identified memory module 134 and uncoupling and removing the identified memory module 134. Advantageously, the thickness of TIM blankets 210 may be small enough to allow an individual TIM blanket 210 to be removed from/positioned on a single memory module 134.

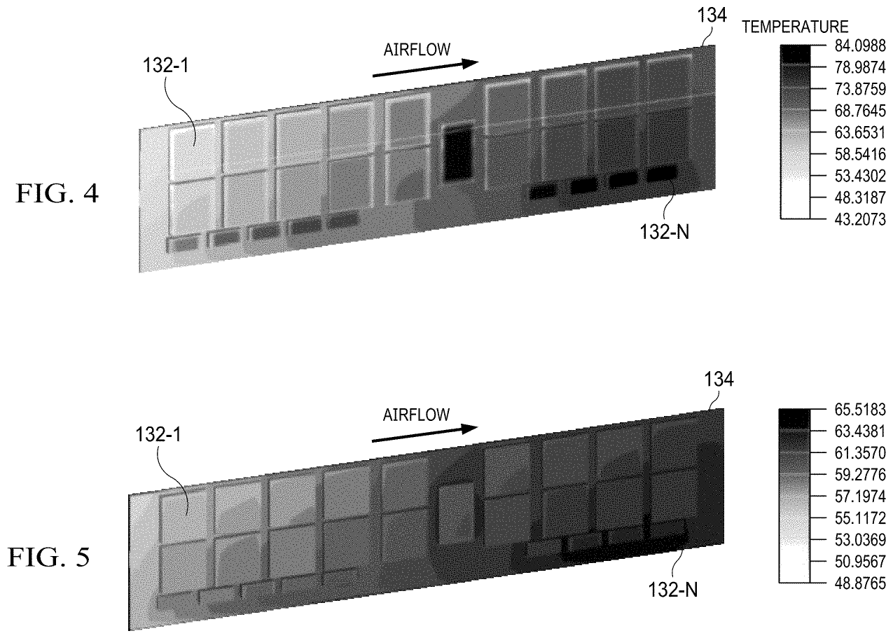

A comparison of temperature profiles of memory module 134 cooled by a convective air cooling system and memory module 134 cooled by an embodiment of system level cooling system 300 indicate system level cooling systems 300 may be capable of increased heat transfer. To illustrate the improvement, FIGS. 4 and 5 depict simulated images of memory module 134 in an array of memory modules 134, wherein FIG. 4 depicts memory module 134 cooled using only convection heat transfer and FIG. 5 depicts memory module 134 cooled using one embodiment of system level cooling system 300.

Referring to FIG. 4, for a memory module 134 positioned in an airflow flowing from left to right, components 132 near the airflow source (i.e., near component 132-1 on the left end of memory module 134) benefit most from convective heat transfer and components 132 located downstream (i.e., near component 132-N on the right end of memory module 134) benefit least from convective airflow and may even be negatively affected. In particular, components 132 near component 132-1 at the left end of memory module 134 reach the lowest temperature (approximately 43° C.) and the operating temperatures increase until components 132 near component 132-N at the right end of memory module 134 reach the highest temperature (approximately 84° C.). The large range (approximately 41° C.) between the highest and lowest operating temperatures (84° C. and 43° C., respectively) indicates convective airflow may not benefit all components 132. Furthermore, a high operating temperature of components 132 may lead to data loss or early failure of memory module 134 or information handling system 100.

FIG. 5 depicts a simulated image of a temperature profile of a memory module 134, illustrating how system level cooling of an array of memory modules 134 may benefit each memory module 134 and may benefit each component 132 on each memory module 134. As depicted in FIG. 5, components 132 near component 132-1 at the left end of memory module 134 reach the lowest temperature (approximately 49° C.) and the operating temperatures increase until components 132 near component 132-N at the right end of memory module 134 reach the highest temperature (approximately 65° C.), indicating components 132 near one end of memory module 134 may still benefit based on the direction of air flowing past system level cooling system 300. However, instead of components 132 having the large range (approximately 41° C.) in operating temperatures associated with only convective airflow discussed above, components 132 may operate within a much smaller range (e.g., approximately 16° C.) between the highest and lowest operating temperatures. Notably, although components 132 near component 132-1 may have a higher operating temperature (e.g., approximately 49° C. vs. approximately 43° C.), components 132 near component 132-N may have a much lower operating temperature (e.g., approximately 65° C. vs. approximately 84° C.). Thus, conductive heat transfer using system level cooling system 300 and/or system level cooling system interface 200 may reduce the range of operating temperatures of memory module 134, which may lead to improved overall performance by memory module 134. Furthermore, conduction of heat transfer along conduction fins 214 may provide a more uniform temperature profile among components 132 on memory module 134, indicating each component 132 is cooled.

The above disclosed subject matter is to be considered illustrative, and not restrictive, and the appended claims are intended to cover all such modifications, enhancements, and other embodiments which fall within the true spirit and scope of the disclosure. Thus, to the maximum extent allowed by law, the scope of the disclosure is to be determined by the broadest permissible interpretation of the following claims and their equivalents, and shall not be restricted or limited by the foregoing detailed description.

What is claimed is:

1. A cooling system interface for an array of memory modules in an information handling system, each memory module comprising a plurality of components, the cooling system interface comprising:
a plurality of thermal interface material (TIM) blankets, each TIM blanket configured for positioning on a memory module;
a heat sink comprising:
a plurality of conduction fins, wherein each conduction fin is configured for slidable contact with at least one TIM blanket and each conduction fin has a rigidity and a thickness to cause conformal contact between the at least one TIM blanket and all components on the memory module; and
a top surface coupled to the plurality of conduction fins.

2. The cooling system interface of claim 1, wherein the top surface comprises a continuous surface.

3. The cooling system interface of claim 1, wherein the top surface comprises a groove for receiving a conduit.

4. The cooling system interface of claim 1, wherein one or more conduction fins of the plurality of conduction fins are formed with a rigidity to cause conformal contact between a TIM blanket of the plurality of TIM blankets and all components on a single memory module.

5. The cooling system interface of claim 1, wherein one or more conduction fins of the plurality of conduction fins are formed with a thickness to cause conformal contact between a first TIM blanket and a first plurality of components on one side of a first memory module and cause conformal contact between a second TIM blanket and a second plurality of components on one side of a second memory module adjacent to the first memory module.

6. A system level cooling system for an array of memory modules, each memory module comprising a plurality of components, the system level cooling system comprising:
a plurality of thermal interface material (TIM) blankets, each TIM blanket configured for positioning on a memory module in the array of memory modules;
a heat sink comprising:
a plurality of conduction fins, wherein each conduction fin is configured for slidable contact with at least one TIM blanket and each conduction fin has a rigidity and a thickness to cause conformal contact between the at least one TIM blanket and all components on the memory module; and
a top surface coupled to the plurality of conduction fins; and
a plurality of convection fins coupled to the top surface.

7. The system level cooling system of claim 6, wherein the top surface comprises a continuous surface.

8. The system level cooling system of claim 6, further comprising a conduit, wherein:
the top surface comprises a groove for receiving the conduit; and
the plurality of convection fins are coupled to the top surface and the conduit.

9. The system level cooling system of claim 6, wherein one or more conduction fins of the plurality of conduction fins are formed with a rigidity to cause conformal contact between the at least one TIM blanket and the plurality components on one side of a single memory module.

10. The system level cooling system of claim 6, wherein one or more conduction fins of the plurality of conduction fins are formed with a thickness to cause conformal contact between a first TIM blanket and a first plurality of components on one side of a first memory module and cause conformal contact between a second TIM blanket and a second plurality of components on one side of a second memory module adjacent to the first memory module.

11. An information handling system, comprising:
a processor subsystem;
a memory subsystem comprising an array of memory modules, each memory module comprising a plurality of components on each side; and
a cooling system comprising:
a plurality of thermal interface material (TIM) blankets, each TIM blanket configured for contact with the plurality of components on at least one side of a memory module in the array of memory modules;
a heat sink comprising:
a plurality of conduction fins, wherein each conduction fin is configured for slidable contact with at least one TIM blanket and each conduction fin has a rigidity and a thickness to cause conformal contact between the TIM blanket and the plurality of components on the at least one side of the memory module; and
a top surface coupled to the plurality of conduction fins; and
a plurality of convection fins coupled to the top surface.

12. The information handling system interface of claim 11, wherein the top surface comprises a continuous surface.

13. The information handling system interface of claim 11, wherein:
the cooling system comprises a conduit;
the top surface comprises a groove for receiving the conduit; and
the plurality of convection fins are coupled to the top surface and the conduit.

14. The information handling system interface of claim 11, wherein one or more conduction fins of the plurality of conduction fins are formed with a rigidity to cause conformal contact between one TIM blanket and the plurality of components on one side of a single memory module.

15. The information handling system interface of claim 11, wherein one or more conduction fins of the plurality of conduction fins are formed with a thickness to cause conformal contact between a first TIM blanket and a first plurality of components on one side of a first memory module and cause conformal contact between a second TIM blanket and a second plurality of components on one side of a second memory module adjacent to the first memory module.

16. The information handling system interface of claim 11, wherein conformal contact comprises contact between the thermal interface material of the at least one TIM blanket and the plurality of components on the at least one side of the memory module such that the thermal interface material conforms to a shape of each component of the plurality of components.

17. The information handling system interface of claim 16, wherein conformal contact comprises contact between the thermal interface material of the at least one TIM blanket and the plurality of components on the at least one side of the memory module such that the thermal interface material is present between adjacent components.

18. The information handling system interface of claim 17, wherein conformal contact comprises contact between the thermal interface material of the at least one TIM blanket and the plurality of components on the at least one side of the memory module such that the thermal interface material contacts at least a portion of a circuit board on which the plurality of components are mounted.

19. The information handling system interface of claim 11, wherein each TIM blanket is configured for individual removal from a memory module.
